(19) United States
(12) Patent Application Publication
(10) Pub. No.: US 2011/0024767 A1
(43) Pub. Date: Feb. 3, 2011

(54) Semiconductor Substrates, Devices and Associated Methods

(76) Inventor: Chien Min Sung, Tansui (TW)

Correspondence Address: THORPE NORTH & WESTERN, LLP., P.O. Box 1219, SANDY, UT, 84091-1219, US

(21) Appl. No.: 12/829,270

(22) Filed: Jul. 1, 2010

Related U.S. Application Data
(60) Provisional application No. 61/230,055, filed on Jul. 30, 2009.

(51) Int. Cl. H01L 29/12; H01L 21/20; H01L 21/30

(52) U.S. Cl. 257/77; 438/478; 438/455; 257/E29.068; 257/E21.09; 257/E21.211

(57) ABSTRACT

Semiconductor substrates and devices having improved performance and cooling, as well as associated methods, are provided. In one aspect, for example, a semiconductor device can include a matrix layer and a plurality of single crystal semiconductor tiles disposed in the matrix layer. The plurality of semiconductor tiles are positioned such that an exposed surface of each of substantially all of the plurality of diamond tiles aligns along a common plane to form a substrate surface. In one aspect, a semiconductor layer is disposed on the substrate surface. In another aspect, the semiconductor layer is a doped diamond layer. In yet another aspect, the semiconductor tiles are doped. In a further aspect, the exposed surface of each of the plurality of semiconductor tiles has a common crystallographic orientation.

### PRIORITY DATA

This application claims the benefit of U.S. Provisional Patent Application Ser. No. 61/230,055, filed on Jul. 30, 2009, which is incorporated herein by reference.

### FIELD OF THE INVENTION

The present invention relates generally to semiconductor substrates, devices, and associated methods. Accordingly, the present invention involves the electrical and material science fields.

### BACKGROUND OF THE INVENTION

In many developed countries, major portions of the populations consider electronic devices to be integral to their lives. Such increasing use and dependence has generated a demand for electronics devices that are smaller and faster. Electrical devices generally include a source of power that is channeled within semiconductor materials to produce a desired effect or effects. In many cases, electrical interactions within the semiconductor materials are highly dependent on the quality of the semiconductor materials themselves. As electrical devices become smaller and the functional demands of such devices increase, high quality semiconductor materials become very important. High quality semiconductor materials can include semiconductors that are single crystal semiconductors.

Semiconductor layers within an electronic device are generally made by depositing semiconductive materials onto one or more substrate materials. Depending on the semiconductor material being made, it can be very difficult if not impossible to obtain single crystal structures using traditional deposition processes.

One problem associated with electrical components is the buildup of heat within the semiconductor material. Electronic components, such as processors, transistors, resistors, capacitors, light-emitting diodes (LEDs), etc., generate significant amounts of heat. As it builds, heat can cause various thermal problems associated with such electronic components. Significant amounts of heat can affect the reliability of an electronic device, or even cause it to fail by, for example, causing burn out or shorting both within the electronic components themselves and across the surface of a printed circuit board. Thus, the buildup of heat can ultimately affect the functional life of the electronic device. This is particularly problematic for electronic components with high power and high current demands.

### SUMMARY OF THE INVENTION

Accordingly, the present invention provides semiconductor substrates and devices having improved performance and cooling, as well as associated methods. In one aspect, for example, a semiconductor device can include a matrix layer and a plurality of single crystal semiconductor tiles disposed in the matrix layer. Non-limiting examples of semiconductor tile materials can include cBN, AlN, SiC, GaN, TiO₂, ZnO, diamond, and combinations thereof. In one aspect, the semiconductor tiles can be cBN, diamond, or a combination thereof. The semiconductor tiles are positioned such that an exposed surface of each of substantially all of the plurality of semiconductor tiles aligns along a common plane to form a substrate surface. In one aspect, a semiconductor layer is disposed on the substrate surface. In another aspect, the semiconductor layer is a doped diamond layer. In yet another aspect, the semiconductor tiles are doped. In a further aspect, the exposed surface of each of the plurality of semiconductor tiles has a common crystallographic orientation.

Numerous matrix materials are contemplated that can be utilized to secure the diamond tiles. In one aspect, the matrix layer can be Si. In another aspect, the matrix layer can be Si and Ge. In yet another aspect, the matrix layer can be a ceramic material. In a further aspect, the matrix layer is an electroplated metal. In one specific aspect, the electroplated metal can be at least one transition metal. In another aspect, the electroplated metal can include at least one of Ni, Cr, Ti, W, and combinations thereof.

The present invention also provides methods of making a semiconductor device. Such a method can include disposing a plurality of single crystal semiconductor tiles on a temporary mold, applying a matrix layer to the temporary mold and the plurality of semiconductor tiles such that the semiconductor tiles are held in position by the matrix layer, and removing the temporary mold to expose the plurality of semiconductor tiles. Various methods are contemplated for applying the matrix layer. For example, in one aspect applying the matrix layer can include applying a molten matrix material to the temporary mold and the plurality of semiconductor tiles, and cooling the molten matrix to form the matrix layer. Numerous matrix materials are contemplated that can be made molten and that are capable of securing semiconductor tiles. In one example, the molten matrix material is Si. In another aspect the molten matrix material includes Si and Ge. In yet another aspect, applying the matrix layer can include electro depositing a metal layer on the temporary mold and the plurality of semiconductor tiles.

The method can additionally include depositing a diamond layer on the plurality of semiconductor tiles after the removal of the temporary substrate. In some cases, the diamond layer can be doped.

In yet another aspect, the present invention encompasses a method of making a semiconductor device that includes providing a matrix layer of a solid material, and attaching a plurality of single crystal semiconductor tiles to the matrix layer such that they are held in position with an exposed surface of each of substantially all of the plurality of semiconductor tiles aligned along a common plane to form a substrate surface. A number of suitable attachment mechanisms, such as mechanically attaching the tiles in a suitable notch, or hole made in the matrix layer may be used to hold the tiles in the matrix. Such friction fit or mechanical bond may further be augmented by the use of adhesives or organic resins, or by the deposition or inclusion of other metal or ceramic materials in and around the tile-matrix interface, such as by electrodeposition of metal, sintering of ceramic powders, etc.

There has thus been outlined, rather broadly, various features of the invention so that the detailed description thereof that follows may be better understood, and so that the present contribution to the art may be better appreciated. Other features of the present invention will become clearer from the following detailed description of the invention, taken with the accompanying claims, or may be learned by the practice of the invention.

### BRIEF DESCRIPTION OF THE DRAWINGS

FIG. 1 is a cross-section view of a semiconductor device according to one embodiment of the present invention.

FIG. 2 is a cross-section view of a semiconductor device according to another embodiment of the present invention.

FIG. 3 is a cross-section view of a semiconductor device being manufactured according to one embodiment of the present invention.

FIG. 4 is a cross-section view of a semiconductor device being manufactured according to another embodiment of the present invention.

FIG. 5 is a cross-section view of a semiconductor device being manufactured according to yet another embodiment of the present invention.

### DETAILED DESCRIPTION OF THE INVENTION

Definitions

In describing and claiming the present invention, the following terminology will be used in accordance with the definitions set forth below.

The singular forms “a,” “an,” and, “the” include plural referents unless the context clearly dictates otherwise. Thus, for example, reference to “a dopant” includes reference to one or more of such dopants, and reference to “the diamond tile” includes reference to one or more of such tiles.

As used herein, “vapor deposited” refers to materials which are formed using vapor deposition techniques. “Vapor deposition” refers to a process of forming or depositing materials on a substrate through the vapor phase. Vapor deposition processes can include any process such as, but not limited to, chemical vapor deposition (CVD) and physical vapor deposition (PVD). A wide variety of variations of each vapor deposition method can be performed by those skilled in the art. Examples of vapor deposition methods include hot filament CVD, rf-CVD, laser CVD (LCVD), laser ablation, conformal diamond coating processes, metal-organic CVD (MOCVD), sputtering, thermal evaporation PVD, ionized metal PVD (IMPVD), electron beam PVD (EBPVD), reactive PVD, and the like.

As used herein, “chemical vapor deposition,” or “CVD” refers to any method of chemically forming or depositing diamond particles in a vapor form upon a surface. Various CVD techniques are well known in the art.

As used herein, “physical vapor deposition,” or “PVD” refers to any method of physically forming or depositing diamond particles in a vapor form upon a surface. Various PVD techniques are well known in the art.

As used herein, “diamond” refers to a crystalline structure of carbon atoms bonded to other carbon atoms in a lattice of tetrahedral coordination known as sp³ bonding. Specifically, each carbon atom is surrounded by and bonded to four other carbon atoms, each located on the tip of a regular tetrahedron. Further, the bond length between any two carbon atoms is 1.54 angstroms at ambient temperature conditions, and the angle between any two bonds is 109 degrees, 28 minutes, and 16 seconds although experimental results may vary slightly. The structure and nature of diamond, including its physical and electrical properties are well known in the art.

As used herein, “distorted tetrahedral coordination” refers to a tetrahedral bonding configuration of carbon atoms that is irregular, or has deviated from the normal tetrahedron configuration of diamond as described above. Such distortion generally results in lengthening of some bonds and shortening of others, as well as the variation of the bond angles between the bonds. Additionally, the distortion of the tetrahedron alters the characteristics and properties of the carbon to effectively lie between the characteristics of carbon bonded in sp³ configuration (i.e. diamond) and carbon bonded in sp² configuration (i.e. graphite). One example of material having carbon atoms bonded in distorted tetrahedral bonding is amorphous diamond.

As used herein, “diamond-like carbon” refers to a carbonaceous material having carbon atoms as the majority element, with a substantial amount of such carbon atoms bonded in distorted tetrahedral coordination. Diamond-like carbon (DLC) can typically be formed by PVD processes, although CVD or other processes could be used such as vapor deposition processes. Notably, a variety of other elements can be included in the DLC material as either impurities, or as dopants, including without limitation, hydrogen, sulfur, phosphorous, boron, nitrogen, silicon, tungsten, etc.

As used herein, “amorphous diamond” refers to a type of diamond-like carbon having carbon atoms as the majority element, with a substantial amount of such carbon atoms bonded in distorted tetrahedral coordination. In one aspect, the amount of carbon in the amorphous diamond can be at least about 90%, with at least about 20% of such carbon being bonded in distorted tetrahedral coordination. Amorphous diamond also has a higher atomic density than that of diamond (176 atoms/cm³). Further, amorphous diamond and diamond materials contract upon melting.

The terms “thermal transfer,” “thermal movement,” and “thermal transmission” can be used interchangeably, and refer to the movement of heat from an area of higher temperature to an area of cooler temperature. It is intended that the movement of heat include any mechanism of thermal transmission known to one skilled in the art, such as, without limitation, conductive, convective, radiative, etc.

As used herein, “substrate” refers to a support surface to which various materials can be joined in forming a semiconductor component or device. The substrate may be any shape, thickness, or material, required in order to achieve a specific result, and includes but is not limited to metals, alloys, ceramics, and mixtures thereof. Further, in some aspects, the substrate may be an existing semiconductor device or wafer, or may be a material which is capable of being joined to a suitable device.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually.

This same principle applies to ranges reciting only one numerical value as a minimum or a maximum. Furthermore, such an interpretation should apply regardless of the breadth of the range or the characteristics being described.

The Invention

The present invention provides semiconductor substrates, devices, and associated methods. Single crystal semiconductor wafers, such as diamond wafers, have been historically difficult to produce, particularly in sizes required for semiconductor devices such as LEDs. The inventors have discovered that a substantially single crystal diamond or other semiconductor wafer can be created by arranging a plurality of semiconductor tiles in a grid or other configuration, and infiltrating the plurality of semiconductor tiles with a matrix material. The semiconductor tiles can be cut along the same crystallographic plane prior to infiltration, so the exposed faces of these tiles will have the same crystallographic orientation. This surface of exposed faces will be a substantially single crystal semiconductor wafer, albeit constructed of individual crystal islands.

It should be noted that, while focusing primarily on diamond tile materials, the discussion herein pertains to all semiconductor materials that can be incorporated into a semiconductor device according to aspects of the present invention, and not just said diamond materials. That being said, a variety of semiconductor materials are contemplated, any of which should be considered to be within the present scope. Non-limiting examples include cBN, AlN, SiC, GaN, TiO₂, ZnO, diamond, and combinations thereof. In one specific aspect, the semiconductor tiles can be diamond. In another specific aspect, the semiconductor tiles can be cBN.

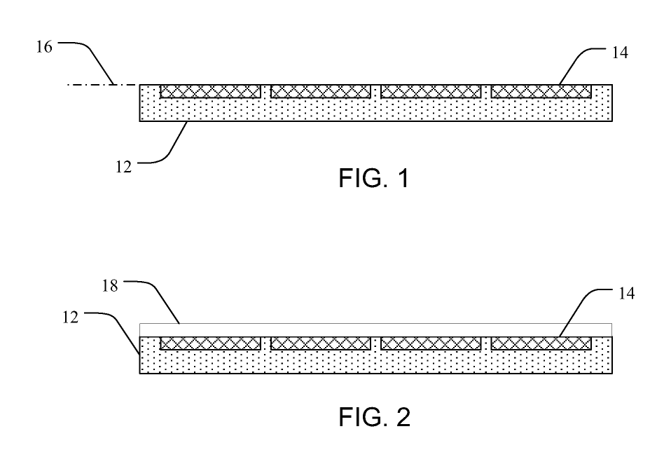

Accordingly, in one aspect of the present invention shown in FIG. 1, a semiconductor device can include a matrix layer 12 and a plurality of single crystal diamond tiles 14 disposed in the matrix layer 12. The exposed surfaces of each of the plurality of diamond tiles can be aligned along a common plane 16 to form a substrate surface. This substrate surface can be utilized for the deposition of semiconductor layers to be included in the semiconductor device. FIG. 2 shows a matrix layer 12 having a plurality of diamond tiles 14 embedded therein, and a semiconductor layer 18 that is disposed on the substrate surface. The semiconductor layer can be one semiconductor layer, or it can be multiple semiconductor layers. In one aspect, the semiconductor layer is a doped diamond layer. In another aspect, the diamond tiles are doped.

Thus a substrate is formed having many beneficial characteristics of single crystal diamond that avoids many of the difficulties associated with the formation of large single crystal structures. Such beneficial characteristics include thermal dissipation, improved LED emission, and the like.

It is to be noted that in an alternative embodiment of the present invention, a solid form matrix may be provided and appropriately notched, etched, or cut outs of a suitable size may be made. The diamond tiles may then be mechanically fitted into such notches, etches, or cut out portions and held in the matrix using merely mechanical forces such as a friction fit, etc., or a combination of mechanical forces and other forces, such as by following up mechanical placement with deposition of additional matrix material around the diamond tiles, or tiles of other material. In addition, such mechanical fit of the diamond tiles may be used regardless of the specific size or type of tile. In some aspects, the tiles may be large single crystal materials. In other aspects they may be smaller sized pieces.

In yet an additional aspect of the invention, a suitable adhesive or organic resin material, including curable polymers may be used in order to hold the tiles in and/or on the matrix material. In some aspects, the tiles may be mechanically fitted and then a suitable adhesive or organic resin applied. The adhesive or resin may then be cured and will bond the tiles to the matrix. A wide range of specific adhesives and resins may be used as required in order to provide a finished product where the tiles are held in place with sufficient strength and durability characteristics. Furthermore, an adhesive or resin may be used to hold the tiles in place on the temporary mold when such mold is used as a part of the fabrication process. This also applies to when the temporary mold is used in a thermally intensive process, such as the deposition of the matrix around the tiles.

In addition to the foregoing, a number of additional attachment mechanism for attaching tiles to the matrix may be used. For example, in one aspect, tiles may be held on the matrix by affixing the tiles to a solid form of the matrix material, surrounding the tiles with graphite and hot pressing the assembly in order to solidify the graphite and bind the tiles to the matrix. In addition, silicon may be infiltrated between the diamonds and solidified to hold the tiles in place on or in the matrix. Further, ceramic materials, for example alumina in powdered form, may be placed around the tiles and sintered in order to hold the diamond in place and bind them to the matrix. Moreover, in another aspect, the tiles may be carbonized along a surface that is to be in contact with the matrix and such carbide materials may then be bonded to the matrix. Hence, the tiles are chemically bonded to the matrix through the carbide bonds.

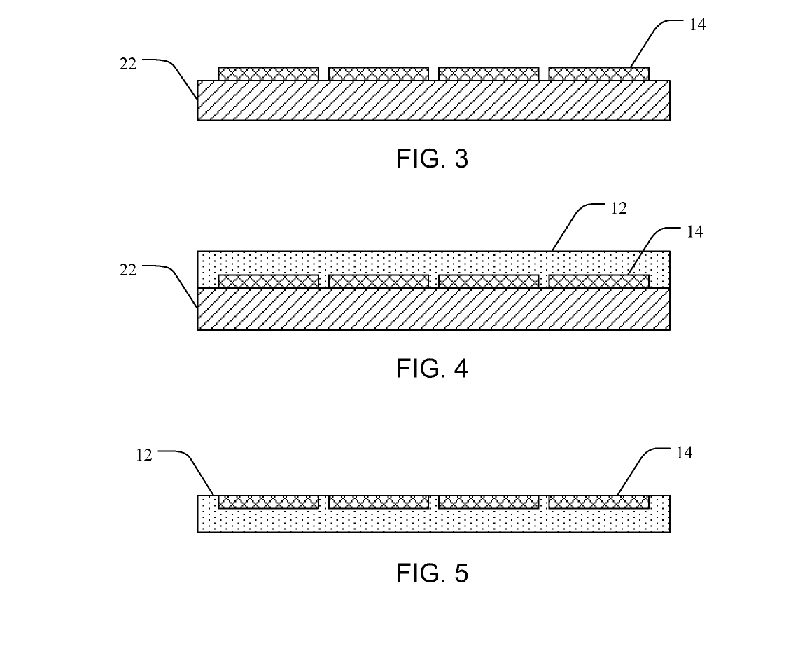

The present invention additionally provides methods for making semiconductor devices. In one aspect, for example, a method of making a semiconductor device can include disposing a plurality of single crystal diamond tiles on a temporary mold, applying a matrix layer to the temporary mold and the plurality of diamond tiles such that the diamond tiles are held in position by the matrix layer, and removing the temporary mold to expose the plurality of diamond tiles. FIGS. 3-6 show steps associated with this process.

Turning to FIG. 3, a plurality of diamond tiles 14 are disposed along a surface of a temporary mold 22. The diamond tiles can be arranged in a variety of patterns depending on the desired configuration of the semiconductor device and the shapes of the diamond tiles, as is discussed below. In one aspect, for example, the tiles can be arranged into a uniform or substantially uniform grid. A grid configuration can be effectively facilitated using square and/or rectangular diamond tiles. Additionally, the spacing between the tiles, for the grid and other configurations, can vary depending on the manufacturing tolerances and the desired configuration of the semiconductor device. In one aspect, for example, the diamond tiles can be positioned relative to one another to cause the diamond tiles to contact one another. In another aspect, the diamond tiles can be spaced apart from one another. Such spacing can vary, however, in one aspect the spacing between diamond tiles is less than about 500 microns. In another aspect, the spacing between diamond tiles is less than about 250 microns. In yet another aspect, the spacing between diamond tiles is less than about 100 microns. In a further aspect, the spacing between diamond tiles is less than about 50 microns. In yet a further aspect, the spacing between diamond tiles is less than about 10 microns. In another aspect, the spacing between diamond tiles is less than about 1 micron. Additionally, it should be noted that the diamond tiles can be spaced in a uniform manner, in a non-uniform manner, or in a mixture of a uniform and non-uniform manner.

It can also be beneficial to temporarily secure the diamond tiles to the temporary substrate so the tiles remain in position during application of the matrix layer. Numerous methods for securing the tiles are contemplated, and any useful method should be seen as being within the present scope. For example, the tiles can be secures with glues, tapes, adhesives, organic resins, structural supports or templates, etc. In one aspect, the tiles can be arranged on the temporary mold and secured with an adhesive such as double stick tape. A refractory powder can be applied across the tiles to thus fill the gaps between the tiles. In the case of molten matrix infiltration, such an infiltrant will cause the refractory powder to be cast such that the tiles are secured. Securing the tiles prevents movement of the tiles in the liquid during infiltration.

As is shown in FIG. 4, a matrix layer 12 is applied to the diamond tiles 14 and to the temporary substrate 22 between and surrounding the diamond tiles 14. The matrix layer can be applied by a variety of methods, all of which are considered to be within the present scope. For example, in one aspect applying the matrix layer can include applying a molten matrix material to the temporary mold and the plurality of diamond tiles and cooling the molten matrix to form the matrix layer. Thus a molten matrix layer can be utilized to infiltrate the plurality of diamond tiles and to thus secure the tiles in a fixed position. Depending on the nature of the matrix layer, the diamond tiles can be mechanically bonded or chemically bonded to the matrix layer. In one aspect, the diamond tiles are chemically bonded to the matrix layer. It should be noted that, particularly for molten matrix materials that do not readily bond to diamond, an interlayer can be utilized to facilitate such chemical bonding.

Various matrix materials can be utilized in the molten process. In one aspect, for example, the matrix material can be Si. Although pure and substantially pure Si materials can be used, in some cases it may be beneficial to include an additional material with the Si material to lower the melting temperature of the molten matrix, thus reducing the chance of damage to the diamond tiles. In one aspect, the additional material can include Ge. Ge effectively alloys with Si and lowers the melting temperature of the molten matrix. Additional matrix materials can include ceramic materials.

One difficulty in using a molten matrix material to secure the diamond tiles relates to the back-conversion of diamond into graphite or amorphous carbon at high temperatures. This problem can be at least partially avoided, however, by infiltrating the diamond tiles under high vacuum conditions. Residue sp2 bonds that do form can be gasified to form methane in a hydrogen atmosphere typical for CVD growth of diamond films.

In another aspect, applying the matrix layer can include electrodepositing a metal layer on the temporary mold and the plurality of diamond tiles. A variety of metal materials are contemplated for use in the metal layer of the present invention, and nearly any metal capable of being electrodeposited should be considered to be within the present scope. The selection of the metal materials can be dependent on the intended use and configuration of the device, the compatibility the diamond layer, and the like. One possible reason for using a metal layer as a matrix layer is the high thermal and electrical conductivity metal materials. As such, metals having a high thermal and/or electrical conductivity can be utilized. In one aspect the metal can include at least one transition metal. In another aspect, non-limiting metals can include Ni, Cr, Ti, W, and combinations and alloys thereof.

In yet another aspect, a graphite matrix can be used to secure the diamond tiles. In this case, while molten graphite would damage the diamond tiles, graphite can be heated to a softened state and hot pressed with the diamond tiles to form the substrate layer. Such a state can be achieved by a variety of methods as would be understood by one of ordinary skill in the art once in possession of the present disclosure. In one example, however, 20 microns of highly graphitized graphite can be pressed at 400 MPa at 1000° C. for 20 minutes. In some cases, diamond particles can be embedded in the graphite and the entire structure could be polished to obtain the smooth substrate surface with the plurality of diamond islands. Polishing process can be particularly beneficial when working with small diamond tiles sizes (e.g. 30/40 mesh or about 500 microns in size) that are difficult to slice and arrange. It should be noted that this process of utilizing diamond particles and subsequently polishing to achieve the substrate surface applies not only to graphite matrix materials, but also to all the matrix layer materials that can be utilized in aspects of the present invention.

Following the application of the matrix layer 12, the temporary mold 22 can be removed to expose the diamond tiles 14, as is shown in FIG. 5. Thus the temporary mold has been used to configure the diamond tiles into a uniform shape, in this case a planar surface. The temporary mold can be removed in a variety of ways, including abrading methods such as grinding, scraping, polishing, chipping, liquid jet, and the like. Temporary mold materials that are susceptible to chemical attack can be removed using a chemical agent. The temporary mold can be removed using such a chemical agent, or it can be removed using such a chemical agent in conjunction with an abrading process. Upon removal of the temporary mold, the diamond tiles may or may not be polished.

Of note is that in some aspects of the invention, heat treating the matrix to cure it with the tiles may result in conversion of the tile material into a different material at the surface thereof. For example, when diamond tiles are used, elevated temperature processing may be used in order to bond or otherwise hold the diamond tiles in the matrix. While temperatures should be controlled in order to prevent excessive back conversion of diamond to graphite, in some aspects, the heat treatment may result in a few layers of graphene being formed along the diamond surfaces exposed from the matrix. Such graphene layer formed in-situ may be useful for acting as a transition material that useful for growing a second material, for example, AlN on the exposed surface of the diamond tiles. Such graphene layers may be formed to be only a few atoms thick, or may be formed substantially thicker depending on the desired transition layer to be formed. The specific thickness of the graphene layer may be controlled by the thermal processing alone, or may be controlled by a combination of thermal processing followed by mechanical polishing, or another post heating step in order to reduce the amount or thickness of graphene on the diamond tile surfaces. In some aspects, the graphene may be epitaxial. In further aspects, graphite may be the layer formed on the exposed tile surfaces as a result of the thermal processing. Such graphite can be polished and thinned in order to reduce thickness and leave a thinner layer of graphene on the exposed diamond tile surfaces. In some aspects, the graphene may be formed as a result of the polishing of graphite. In other aspects, the graphene may be revealed by the polishing of graphite.

The single crystal diamond tiles of the present invention can be made from a variety of materials and processes. For example, the diamond tiles can be cut or cleaved from synthetic or natural diamond that is of a single crystal. In this way, thin diamond tiles having the same crystallographic orientation can be formed from a diamond source. Thus the size of the diamond tiles can correlate with the size of the diamond being cleaved. For example, a 1 mm diamond can be oriented to a particular cleavage plane and sliced into a plurality of tiles. Depending on the cleavage plane, the resulting tiles will be 1 mm in size and have an orientation consistent with the cleavage plane (i.e. cubic, hexagonal, and the like). Additionally, the diamond source can be doped during diamond growth. The resulting diamond tiles with thus be doped diamond tiles.

The diamond tiles can be of any thickness that is possible to manipulate and embed in a matrix layer. In some cases, the diamond tiles can be cleaved from a diamond source, and thus require little or no post process polishing is necessary. In other cases, diamond particles can be utilized that can require substantial polishing. Thus the thickness of the diamond tiles, in some cases, can depend on the process used to make the semiconductor device. In one aspect, however, the diamond tile can be less than about 1000 microns in size. In another aspect, the diamond tile can be less than about 500 microns in size. In yet another aspect, the diamond tile can be less than about 250 microns in size. In a further aspect, the diamond tile can be less than about 100 microns in size. In yet a further aspect, the diamond tile can be less than about 50 microns in size.

In addition to size, the diamond tiles can be of any desired shape. Non-limiting examples of such shapes include square, rectangle, circle, elliptical, polyhedral, triangular, hexagonal, octagonal, and the like. The tiles can also, in some cases, have an undefined shape, such as would be the case for tiles cut from a crystal having irregular boundaries.

As has been described, a semiconductor layer can be disposed on the diamond tile/substrate surface. Numerous semiconductor materials are known, and any such material can be deposited on the diamond tiles and would be considered to be within the present scope. In one aspect, however the semiconductor layer can be a nitride layer, such as AlN, GaN, BN, (Al,B)N, and the like. Such a semiconductor layer can additionally be doped. It is also contemplated that a doped diamond layer can be disposed on the diamond tiles to create a semiconductor substrate. Additionally, depositing such a doped diamond layer onto doped diamond tiles can create semiconductive structures such as p-n and p-i-n junctions, and the like. The deposited diamond layer can be CVD diamond, DLC, amorphous diamond, and combinations thereof. Diamond materials used as semiconductive layers and/or diamond tiles have various useful properties that provide benefit to resulting semiconductor devices.

For example, diamond materials have excellent thermal conductivity properties that make them ideal for incorporation into electronics devices. The transfer of heat that is present in an electronic device can thus be accelerated from the device through a diamond material. It should be noted that the present invention is not limited as to specific theories of heat transmission. As such, in one aspect the accelerated movement of heat from inside the device can be at least partially due to heat movement into and through a diamond layer. Due to the heat conductive properties of diamond, heat can rapidly spread laterally through the diamond layer. Heat present around the edges of the device, and thus further away from the heat source, will be more rapidly dissipated into the air or into surrounding structures, such as heat spreaders or device supports. Additionally, diamond layers having a portion of surface area exposed to air will more rapidly dissipate heat from a device in which such a layer is incorporated. Because the thermal conductivity of diamond is greater than the thermal conductivity of other materials in the electronic device or other structure to which it is thermally coupled, a heat sink or spreader is established by the diamond layer. Thus heat that builds up in the device is drawn into the diamond layer and spread laterally to be discharged from the device. Such accelerated heat transfer can result in electronic devices with much cooler operational temperatures. Additionally, the acceleration of heat transfer not only cools an electronic device, but may also reduce the heat load on many associated electronic components.

It should be understood that the following is a very general discussion of diamond deposition techniques that may or may not apply to a particular layer or application, and that such techniques may vary widely between the various aspects of the present invention. Generally, diamond layers may be formed by any means known, including various vapor deposition techniques. Any number of known vapor deposition techniques may be used to form these diamond layers. The most common vapor deposition techniques include chemical vapor deposition (CVD) and physical vapor deposition (PVD), although any similar method can be used if similar properties and results are obtained. In one aspect, CVD techniques such as hot filament, microwave plasma, oxyacetylene flame, rf-CVD, laser CVD (LCVD), metal-organic CVD (MOCVD), laser ablation, conformal diamond coating processes, and direct current arc techniques may be utilized. Typical CVD techniques use gas reactants to deposit the diamond or diamond-like material in a layer, or film. These gases generally include a small amount (i.e. less than about 5%) of a carbonaceous material, such as methane, diluted in hydrogen. A variety of specific CVD processes, including equipment and conditions, as well as those used for boron nitride layers, are well known to those skilled in the art. In another aspect, PVD techniques such as sputtering, cathodic arc, and thermal evaporation may be utilized. Further, specific deposition conditions may be used in order to adjust the exact type of material to be deposited, whether DLC, amorphous diamond, or pure diamond.

An optional nucleation enhancing layer can be formed on the matrix layer in order to improve the quality and deposition time of a diamond layer. Specifically, a diamond layer can be formed by depositing applicable nuclei, such as diamond nuclei, on the matrix layer and then growing the nuclei into a film or layer using a vapor deposition technique. It should be noted that diamond will readily nucleate on the diamond tiles. In one aspect of the present invention, a thin nucleation enhancer layer can be coated upon the matrix layer to enhance the growth of the diamond layer. This nucleation enhancing layer can also be applied to the diamond tiles in order to more effectively coat the exposed surface area. Diamond nuclei are then placed upon the nucleation enhancer layer, and the growth of the diamond layer proceeds via CVD or PVD as possible deposition techniques.

A variety of suitable materials will be recognized by those in skilled in the art which can serve as a nucleation enhancer. In one aspect of the present invention, the nucleation enhancer may be a material selected from the group consisting of metals, metal alloys, metal compounds, carbides, carbide formers, and mixtures thereof. Examples of carbide forming materials may include, without limitation, tungsten (W), tantalum (Ta), titanium (Ti), zirconium (Zr), chromium (Cr), molybdenum (Mo), silicon (Si), and manganese (Mn). Additionally, examples of carbides include tungsten carbide (WC), silicon carbide (SiC), titanium carbide (TiC), zirconium carbide (ZrC), and mixtures thereof among others.

The nucleation enhancer layer, when used, is a layer which is thin enough that it does not to adversely affect the thermal transmission properties of the diamond layer. In one aspect, the thickness of the nucleation enhancer layer may be less than about 0.1 micrometers. In another aspect, the thickness may be less than about 10 nanometers. In yet another aspect, the thickness of the nucleation enhancer layer is less than about 5 nanometers. In a further aspect of the invention, the thickness of the nucleation enhancer layer is less than about 3 nanometers.

Various methods can be employed to increase the quality of the diamond in the nucleation surface of the diamond layer that is created by various deposition techniques. For example, diamond particle quality can be increased by reducing the methane flow rate, and increasing the total gas pressure during the early phase of diamond deposition. Such measures decrease the decomposition rate of carbon, and increase the concentration of hydrogen atoms. Thus a significantly higher percentage of the carbon will be deposited in a sp³ bonding configuration, and the quality of the diamond nuclei (and thus the diamond layer) formed is increased. Additionally, the nucleation rate of diamond particles deposited on the dielectric layer or the nucleation enhancer layer may be increased in order to reduce the amount of interstitial space between diamond particles. Examples of ways to increase nucleation rates include, but are not limited to; applying a negative bias in an appropriate amount, often about 100 volts, to the growth surface; polishing the growth surface with a fine diamond paste or powder, which may partially remain on the growth surface; and controlling the composition of the growth surface such as by ion implantation of C, Si, Cr, Mn, Ti, V, Zr, W, Mo, Ta, and the like by PVD or PECVD. PVD processes are typically at lower temperatures than CVD processes and in some cases can be below about 200° C. such as about 150° C. Other methods of increasing diamond nucleation will be readily apparent to those skilled in the art.

In one aspect of the present invention, the diamond layer may be formed as a conformal diamond layer. Conformal diamond coating processes can provide a number of advantages over conventional diamond film processes. Conformal diamond coating can be performed on a wide variety of substrates, including non-planar substrates. A growth surface can be pretreated under diamond growth conditions in the absence of a bias to form a carbon film. The diamond growth conditions can be conditions that are conventional CVD deposition conditions for diamond without an applied bias. As a result, a thin carbon film can be formed which is typically less than about 100 angstroms. The pretreatment step can be performed at almost any growth temperature such as from about 200° C. to about 900° C., although lower temperatures below about 500° C. may be preferred. Without being bound to any particular theory, the thin carbon film appears to form within a short time, e.g., less than one hour, and is a hydrogen terminated amorphous carbon.

Following formation of the thin carbon film, the growth surface can then be subjected to diamond growth conditions to form a conformal diamond layer. The diamond growth conditions may be those conditions that are commonly used in traditional CVD diamond growth. However, unlike conventional diamond film growth, the diamond film produced using the above pretreatment steps results in a conformal diamond film that typically begins growth substantially over the entire growth surface with substantially no incubation time. In addition, a continuous film, e.g. substantially no grain boundaries, can develop within about 80 nm of growth. Diamond layers having substantially no grain boundaries may move heat more efficiently than those layers having grain boundaries.

The resulting electronic substrates can be utilized for any application for which such a substrate would be useful. General examples of such devices can include LEDs, laser diodes, p-n junction devices, p-i-n junction devices, SAW and BAW filters, electronic circuitry, transistors, CPUs, and the like. LEDs made according to the present invention can emit UV at 235 nm, and are therefore desirable for phosphor fluorescence. UV LEDs combined with RGB phosphorescence can be very useful in the creation of tunable white light.

In another aspect of the present invention, cBN tiles can be utilized rather than diamond tiles. Diamond is an indirect band semiconductor. As such the electron transition may need to be assisted by tuning of the band structure. Consequently, in some situations diamond LEDs can be limited in operating within a certain temperature range. Additionally, diamond materials can be difficult to dope, particularly with P and N. As a result, resistivity can be high and current can be low.

Many of this issues can be resolved using cBN island wafers similar to the diamond island wafers described above. For example, cBN, like all nitride LEDs has a direct band gap. Moreover, cBN grades easily into AlN, GaN, and InN. Such a gradation can allow the emission of deep UV (e.g. band gap>6 eV) to UV (AlN), blue (GaN), and red (InN), including any region there between.

Accordingly, the present invention provides a semiconductor layer including a matrix layer and a plurality of single crystal cBN tiles disposed in the matrix layer such that an exposed surface of each of substantially all of the plurality of cBN tiles aligns along a common plane to form a substrate surface. It should be noted that the manufacturing and material details described in the diamond tile section should be applied to cBN materials, provided the details are relevant.

Thus cBN particles can be placed on a flat temporary mold of a material such as hBN, and a molten ceramic material can be used to infiltrate and cast the cBN particles into a solid structure. Examples of ceramics can include a Si—Ge alloy, or cBN solvents and catalysts such as Mg₃N₂, Li₃N₂, (Ga,In)N, and the like. High melting point nitrides, such as TiN, can also be added to reinforce the matrix.

Because cBN is much softer than diamond, the cBN particles protruding from the matrix material can be polished with diamond lapping tools. Alternatively, cBN tiles can be infiltrated with the matrix layer as was described above.

### Examples

The following examples illustrate various techniques of making semiconductor devices according to aspects of the present invention. However, it is to be understood that the following are only exemplary or illustrative of the application of the principles of the present invention. Numerous modifications and alternative compositions, methods, and systems can be devised by those skilled in the art without departing from the spirit and scope of the present invention. The appended claims are intended to cover such modifications and arrangements. Thus, while the present invention has been described above with particularity, the following Examples provide further detail in connection with several specific embodiments of the invention.

### Example 1

A tungsten plate is polished and sputter coated with Ti (one micron thick). A double sided adhesive is applied on the surface. Cubical diamond crystals (e.g. 1 mm) pre-coated with Ti (1 micron) are placed on the adhesive with a tight packing. The temporarily held tiles are then heated in a vacuum furnace (e.g. 900 C) to form a TiC interface between the Ti and the diamond. The adhesive is vaporized during the heating process around 500 C. The attached diamond tiles are then packed with WC powder inside a column made of hexagonal boron nitride. The column is utilized to contain the charge.

An infiltrant (e.g. a Ni—Cu alloy) powder is place on the top of the assembly, and the assembly is heated in vacuum to about 1000° C. for 30 minutes. The infiltrant melts and bonds to WC powder and also to the diamond via the coating of Ti (note that Ni—Cu alloy cannot wet the diamond, but it can form an alloy with Ti).

### Example 2

A polished silicon wafer is used as the mold of Example 1. Ti coated AlN particles are placed on the surface of the mold, and the assembly is vacuum heated to allow bonding of AlN on Si via Ti. The bonded assembly is infiltrated with a Ni—Si alloy to form a consolidated wafer.

### Example 3

SiC tiles are disposed with an adhesive on a mold made of graphite. The mold is then packed with Nichrobraze LM alloy that has a solidus of about 970° C. The charge is hot pressed at 40 Mpa and 900° C. so the LM powder is sintered with a porosity of less than about 3 V %. The SiC crystals are ground to expose the large surfaces and then they are polished. This SiC “island wafer” can be used to grow GaN with a buffer layer of AlN by MOCVD. Subsequently, the wafer is dissolved in aqua regia to produce a SiC supported GaN LED.

### Example 4

A cBN wafer is made by bonding Ti coated cBN tiles to a matrix layer, where the cBN tiles are doped with Si or C to render them N-type semiconductor. The matrix layer contains TiN powder that is infiltrated by Ni—Cu. The wafer is polished and wafer bonded to a boron doped CVD diamond layer. A large surface LED is thus formed by metallizing part of the N-type semiconductor and boron doped diamond. Wafer bonding can be achieved by vacuum pressing the two polished surfaces around 40 MPa under high vacuum.

### Example 5

Cubic boron nitride crystals (about 300 microns in size) with N-type silicon doping are made by converting hexagonal boron nitride with a Li₃N₂—BN solvent at 5 GPa and 1400 C in a cubic press. The recovered crystals are sized by sieving and shape separated by an asymmetrical vibrating table. The crystals are thoroughly cleaned in acid and in detergent and fully dried. Subsequently, they are coated with titanium metal (about 1 micron thick) by packing them in TiH2 powder and heated to 900 C for 30 minutes (alternatively a CVD method may be used by thermally reduce TiCl₄ gas with hydrogen).

The coated crystals are tiled on a polished tungsten mold in such a way that the largest flat surfaces are coplanar with the mold surface. The tiled crystals are heated under vacuum to cause the bonding of the Ti with the W. A mixture of silicon and nickel is then added and the mold is reheated in vacuum. The molten Si—Ni bonds to the Ti coated cBN crystals. Due to the refractory nature of the tungsten mold, cBN crystals are not floated or disturbed during the infiltration process.

After cooling, the bonded cBN islands are separated from the mold and ground with a vitrified diamond wheel. Subsequently, the cBN islands are polished with an iron plate fed with slurry impregnated with micron diamond powder. The surface is finally polished with a polyurethane pad that is coated with a CMP slurry. The final cBN islands have a roughness of a few angstroms. Due to the super hard nature of cBN materials, these crystals protrude above the matrix of Si—Ni during the grinding and polishing processes.

A polished diamond wafer grown by a CVD process that is doped with boron is used as a P-type material. The diamond wafer is pressed against the cBN island wafer to form intimate mechanical contacts under vacuum with a moderate temperature. Wafer bonding is formed at the contact points of the flat surfaces. Due to the island nature, the bonding stress is relieved around the islands. After the wafer bonding, the silicon substrate that supports the boron doped diamond film is etched away by soaking in a NaOH solution. After cleaning, the wafer is P-type polycrystalline diamond on a N-type CBN island wafer. Due to the conductive nature of both boron doped diamond and the Si—Ni matrix, the bonded wafers can be used as a large area LED capable of emitting UV with intense light. Due to the built in diamond film as the heat spreader and the fact that cBN crystals also have high thermal conductivity, the wafer sized LED can sustain high power input with minimal failure.

Of course, it is to be understood that the above-described arrangements are only illustrative of the application of the principles of the present invention. Numerous modifications and alternative arrangements may be devised by those skilled in the art without departing from the spirit and scope of the present invention and the appended claims are intended to cover such modifications and arrangements. Thus, while the present invention has been described above with particularity and detail in connection with what is presently deemed to be the most practical and preferred embodiments of the invention, it will be apparent to those of ordinary skill in the art that numerous modifications, including, but not limited to, variations in size, materials, shape, form, function and manner of operation, assembly and use may be made without departing from the principles and concepts set forth herein.

What is claimed is:

1. A semiconductor device, comprising:
a matrix layer; and
a plurality of single crystal semiconductor tiles disposed in the matrix layer such that an exposed surface of each of substantially all of the plurality of semiconductor tiles aligns along a common plane to form a substrate surface.

2. The semiconductor device of claim 1, further comprising a semiconductor layer disposed on the substrate surface.

3. The semiconductor device of claim 2, wherein the semiconductor layer is a doped diamond layer.

4. The semiconductor device of claim 1, wherein the semiconductor tiles includes a semiconductor material selected from the group consisting of cBN, AlN, SiC, GaN, TiO₂, ZnO, diamond, and combinations thereof.

5. The semiconductor device of claim 1, wherein the semiconductor tiles includes a semiconductor material selected from the group consisting of diamond, cBN, and combinations thereof.

6. The semiconductor device of claim 1, wherein the plurality of semiconductor tiles are doped.

7. The semiconductor device of claim 1, wherein the matrix layer is a ceramic material.

8. The semiconductor device of claim 1, wherein the matrix layer is Si.

9. The semiconductor device of claim 8, wherein the matrix layer includes Ge.

10. The semiconductor device of claim 1, wherein the matrix layer is an electroplated metal.

11. The semiconductor device of claim 10, wherein the metal includes at least one transition metal.

12. The semiconductor device of claim 10, wherein the metal includes a member selected from the group consisting of Ni, Cr, Ti, W, and combinations thereof.

13. The semiconductor device of claim 1, wherein the exposed surface of each of the plurality of semiconductor tiles has a common crystallographic orientation.

14. A method of making a semiconductor device, comprising:
disposing a plurality of single crystal semiconductor tiles on a temporary mold;
applying a matrix layer to the temporary mold and the plurality of semiconductor tiles such that the semiconductor tiles are held in position by the matrix layer; and
removing the temporary mold to expose the plurality of semiconductor tiles.

15. The method of claim 14, wherein applying the matrix layer includes:
applying a molten matrix material to the temporary mold and the plurality of semiconductor tiles; and
cooling the molten matrix to form the matrix layer.

16. The method of claim 15, wherein the molten matrix material is Si.

17. The method of claim 16, wherein the molten matrix material includes Ge.

18. The method of claim 14, wherein applying the matrix layer includes electrodepositing a metal layer on the temporary mold and the plurality of semiconductor tiles.

19. The method of claim 14, further comprising depositing a diamond layer on the plurality of semiconductor tiles after the removal of the temporary substrate.

20. A method of making a semiconductor device, comprising:
providing a matrix layer of a solid material; and
attaching a plurality of single crystal semiconductor tiles to the matrix layer such that they are held in position with an exposed surface of each of substantially all of the plurality of semiconductor tiles aligned along a common plane to form a substrate surface.
